(19) United States
(12) Patent Application Publication
(10) Pub. No.: US 2014/0231251 A1
(43) Pub. Date: Aug. 21, 2014

(54) GAS SUPPLY MEMBER, PLASMA PROCESSING APPARATUS AND METHOD OF FABRICATING GAS SUPPLY MEMBER

(71) Applicant: Kabushiki Kaisha Toshiba, Minato-ku (JP)

(72) Inventors: Hisashi Hashiguchi, Mie-ken (JP); Makoto Saito, Ishikawa-ken (JP); Hideo Eto, Mie-ken (JP)

(73) Assignee: Kabushiki Kaisha Toshiba, Minato-ku (JP)

(21) Appl. No.: 14/180,712

(22) Filed: Feb. 14, 2014

(30) Foreign Application Priority Data
Feb. 15, 2013 (JP) 2013-028422

(51) Int. Cl. H01J 37/32

(52) U.S. Cl. CPC H01J 37/32009
USPC 204/298.33; 427/402; 427/401; 427/248.1; 427/376.1; 427/535; 427/554

(57) ABSTRACT

An aspect of the present embodiment, there is provided a gas supply member includes a body, and a gas supply path penetrating into the body, the gas supply path including a first channel at an inlet side and a second channel connected to the first channel at an outlet side, the first channel having a first diameter and a diameter of the second channel being monotonically increased towards the outlet side from the first diameter to a second diameter, wherein an alumina film is provided on a first sidewall of the first channel, an yttrium-containing film is provided on a second sidewall of the second channel and a surface of the body at the outlet side.

### CROSS REFERENCE TO RELATED APPLICATION

This application is based upon and claims the benefit of priority from prior Japanese Patent Application No. 2013-028422, filed on Feb. 15, 2013, the entire contents of which are incorporated herein by reference.

### FIELD

Exemplary embodiments described herein generally relate to a gas supply member, a plasma process apparatus and a method of fabricating a gas supply member.

### BACKGROUND

In processing steps of fabricating a semiconductor device, many plasma processing apparatuses are utilized in performing Reactive Ion Etching (RIE). In the plasma processing apparatus utilizing such RIE, etching is performed by introducing fluorine gas, chlorine gas or the like to generate plasma in a vacuum chamber with low pressure state.

Accordingly, an inner wall or members constituting inner portions are exposed in plasma to be easily corrosive, so that material having higher resistance to plasma such as yttria, alumina or the like is coated as a protective film in the vacuum chamber.

Problems described below are generated in a gas supply member including a gas supply path and an exhaust port set at a gas downstream side. In the gas supply member, a porous alumina film may be provided on a surface of the exhaust port of a shower head and an yttria-containing film may be provided on the porous alumina film. In such a case, cracks are generated in the alumina film due to a thermal expansion difference between the alumina film and aluminum as a material of the main body. Namely, the cracks are generated in the alumina film by expansion of the main body to introduce crack generation in the yttria-containing film on the alumina film. As a result, yttria particles in the yttria film escapes from the yttria film by the crack generation in the alumina film to fly in the vacuum chamber of the plasma processing apparatus.

### BRIEF DESCRIPTION OF THE DRAWINGS

FIG. 1 is a cross-sectional view showing a constitution of a plasma processing apparatus according to a first embodiment;

FIG. 2 is a cross-sectional view showing a gas supply member according to the first embodiment;

FIGS. 3A-3D are cross-sectional views showing a method of fabricating the gas supply member according to the first embodiment;

FIG. 4 is a cross-sectional view showing a gas supply member according to a comparative case;

FIG. 5 is a cross-sectional view showing a gas supply member according to a second embodiment.

### DETAILED DESCRIPTION

An aspect of the present embodiment, there is provided a gas supply member includes a body, and a gas supply path penetrating into the body, the gas supply path including a first channel at an inlet side and a second channel connected to the first channel at an outlet side, the first channel having a first diameter and a diameter of the second channel being monotonically increased towards the outlet side from the first diameter to a second diameter, wherein an alumina film is provided on a first sidewall of the first channel, an yttrium-containing film is provided on a second sidewall of the second channel and a surface of the body at the outlet side.

Another aspect of the present embodiment, there is provided a plasma processing apparatus, including a vacuum chamber, a holding unit configured to hold a sample to be processed in the vacuum chamber, a plasma generation unit configured to generate plasma in gas introduced in the vacuum chamber, and a gas supply member including, a body and a gas supply path penetrating into the body, the gas supply path including a first channel at an inlet side and a second channel connected to the first channel at an outlet side, the first channel having a first diameter and a diameter of the second channel being monotonically increased towards the outlet side from the first diameter to a second diameter, a surface of the gas supply member being placed to be opposed to the holding unit, wherein an alumina film is provided on a first sidewall of the first channel, an yttrium-containing film is provided on a second sidewall of the second channel and a surface of the body at the outlet side.

Another aspect of the present embodiment, there is provided a method of fabricating a gas supply member includes a method of fabricating a gas supply member, including providing a gas supply path penetrating into a body, the gas supply path including a first channel at an inlet side and a second channel connected to the first channel at an outlet side, the first channel having a first diameter and a diameter of the second channel being monotonically increased towards the outlet side from the first diameter to a second diameter providing an alumina film on a first sidewall of the first channel and a second sidewall of the second channel, removing the alumina film on a second sidewall of the second channel and a surface of the body at the outlet side providing an yttrium-containing film on the second sidewall of the second channel and the surface of the body at the outlet side, and removing the yttrium-containing film on the alumina film.

Embodiments will be described below in detail with reference to the attached drawings mentioned above. Throughout the attached drawings, similar or same reference numerals show similar, equivalent or same components, and the description is not repeated. Further, cross-sectional views described as films or the like in the embodiments are schematically illustrated. Accordingly, a relation between a thickness and a width in each of the films, a thickness ratio between each of the layers, or the like is different from real values.

### First Embodiment

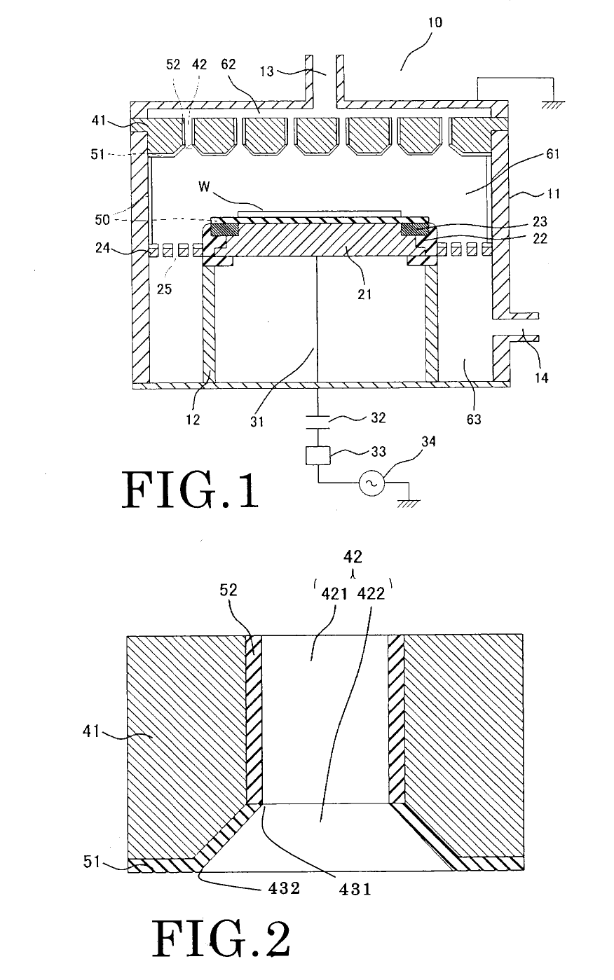

FIG. 1 is a cross-sectional view schematically showing a constitution of a plasma processing apparatus according to the embodiment, for an example. An RIE apparatus is illustrated as a plasma processing apparatus 10, for example. The plasma processing apparatus 10 has a vacuum chamber 11 which is made from aluminum. The vacuum chamber 11 is electrically grounded.

A support table 21 is provided in the vacuum chamber 11. The support table 21 horizontally supports a wafer to be processed W as a process object and acts as a lower electrode. A holding mechanism (not shown) including an electro-static chuck mechanism or the like is provided on a surface of the support table 21. The electrostatic chuck mechanism electrostatically adsorbs the wafer to be processed W. An insulating ring 22 is provided to cover both a side surface and a periphery portion of a bottom surface of the support table 21. A focus ring 23 is provided on an outer perimeter of an upper portion of the support table 21 covered with the insulating ring 22. The focus ring 23 is a member which is provided to adjust electric field not to deviate in a vertical direction at a periphery portion of the wafer to be processed W, when the wafer to be processed W is etched. The direction is perpendicular to the wafer to be processed W.

The support table 21 is positioned near a center of the vacuum chamber 11 and is supported on the support unit 12 through the insulating ring 22. The support unit 12 is vertically extended in an upper direction as a tube shape from a bottom wall near the center of the vacuum chamber 11. A baffle board 24 is provided between the insulating ring 22 and a sidewall of the vacuum chamber 11. The baffle board 24 includes a plurality of gas exhaust pores 25 which penetrates in a thickness direction of the baffle board. A power feed line 31 which supplies radio frequency power is provided to be connected to the support table. The power feed line 31 is connected to a blocking condenser 32, a matching box 33 and a radio frequency power supply 34. Radio frequency power with a prescribed frequency is supplied from the radio frequency power supply 34 to the support table 21.

A shower head 41 acting as an upper electrode is provided at an upper side of the support table 21 to be corresponded to the support table 21 which is act as a lower electrode. The shower head 41 is fixed at a sidewall near an upper side of the vacuum chamber 11 separated from the support table 21 with a prescribed distance to be corresponded to the support table 21 in parallel. In such a structure, a parallel plate electrode is constituted with the shower head 41 and the support table 21. A plurality of gas supply paths 42, which are inserted in a plate direction, is provided in the shower head 41.

A gas inlet 13 is provided at the upper side of the vacuum chamber 11. Process gas is provided from the gas inlet 13 into the vacuum chamber 11. A gas supply unit (not shown) is connected to the gas inlet 13 through pipes.

A gas outlet 14 is provided to the vacuum chamber 11 under the support table 21 and the baffle plate 24. A vacuum pump (not shown) is connected to the gas outlet 14 through a pipe.

In such a structure, a space separated by the shower head 41 and both the support table 21 and the baffle plate 24 in the vacuum chamber 11, is set as a plasma processing unit 61. An upper space separated by the shower head 41 in the vacuum chamber 11 is set as a gas supply unit 62. A lower space in the vacuum chamber 11 separated by the support table 21 and the baffle plate 24 is set as a gas exhaust unit 63.

Surfaces of members constituting the above structure to contact to a plasma generation area, namely, each of the surface of the members in the plasma processing unit 61 is covered with a protective film 50. Specifically, the protective film 50 containing yttria, which is called a yttria film hereinafter, is formed on an inner wall of the vacuum chamber 11 constituting the plasma processing unit 61, a surface of the shower head 41 at the side of the plasma processing unit 61, a surface of the baffle plate 24 at the side of the plasma processing unit 61, a surface of the focus ring 23, and a surface of the support table 23 at the side configured to be placed the wafer to be processed W.

An outline of processing steps by using the plasma processing apparatus 10 described above is explained below. First, the wafer to be processed W is placed on the support table 21 to be fixed by electrostatic chuck mechanism. Next, the vacuum chamber 11 is evacuated by the vacuum pump (not shown) which is connected to the gas outlet 14. In the evacuation, the gas exhaust unit 63 and the plasma processing unit 61 are connected through gas exhaust pores 25 provided in the baffle plate 24, and the plasma processing unit 61 and the gas supply unit 62 are connected through the gas supply paths 42 in the shower head 41. Accordingly, all space in the vacuum chamber 11 can be evacuated by the vacuum pump connected to the gas outlet 14.

When a pressure in the vacuum chamber 11 reach a prescribed value, a process gas is supplied from the gas supply system (not shown) to the gas supply unit 62 to be supplied into the plasma processing unit 61 through gas supply paths 42. When pressure in the plasma processing unit 61 reach a prescribed value, radio frequency power is applied to the support table, which is the lower electrode, to generate plasma in the plasma processing unit 61, where the shower head 41, which is the upper electrode, is grounded. As the radio frequency power is applied to the lower electrode, a potential gradient is generated between the plasma and the wafer to be processed W to accelerate ions in the plasma gas to the support table, so that the wafer to be processed W can be etched.

FIG. 2 is a cross-sectional view showing a gas supply member according to the first embodiment. A body of the gas supply member is the shower head 41. Each of the gas supply path 42 is provided in the gas supply member. As shown in FIG. 2, for example, the gas supply path 42 is provided to penetrate into a member of the shower head 41 from an upper surface towards a lower surface (a surface at a side of gas downstream) of the shower head 41. The gas supply path 42 includes a first channel 421 with a first diameter and an exhaust port 422 connected to the first channel 421. The exhaust port 422 is a second channel in which a diameter is monotonically increased from one end portion connected to the channel 421 with the first diameter to the other end with a second diameter being larger than the first diameter. The shower head 41 has a larger opening near the outlet of the exhaust port 422, for example. Consequently, the shower head 41 is processed to have a taper shape with a taper side surface. Aluminum can be used as a material of the member of the shower head 41, for example

In such the shower head 41, an alumina film 52 acting a protective film is provided on a sidewall of the first channel 421 to near a bend portion 431. In the bend portion 431, a standard surface in a plurality of surfaces, each of which is not parallel, is set and each of other surfaces is connected to the standard surface in a condition with an angle larger than 90 degrees to the standard surface to form a projection portion. An yttria film 51 can be provided on the alumina film 5 2 near the bend portion 431. However, the yttria film 51 may be generally provided on the alumina film 52.

The yttria film 51 acting as the protective film is provided on a sidewall of the exhaust port 422 and a surface near a bend portion 432 which is one main surface of the shower head 41, at the downstream side in the shower head 41. The yttria film formed near a sidewall of a bend portion 431 has nearly a same plane as the sidewall surface plane of the first channel. In the above case, the yttria film is positioned near a boundary between the first channel 421 and the exhaust port 422. A ring structure formed by the yttria film near the bend portion 431 at the upper side of the exhaust port 422 has nearly the same diameter as the first diameter. The protective film is composed of an yttria film with a thickness of 50-100 μm, for example.

An yttria film formed on the member to be formed as a film is normally used as the yttria film 51, for example. Further, the yttria film 51 is melted to be solidified in the thickness range of the yttria film 51 can be used as a melt-solidification film. In such the case, whole thickness of the yttria film can be made as the melt-solidification film. However, it is not restricted to the above case. A stacked structure can be also used. In the stacked structure, a melt-solidification film and a portion of the yttria film 51 without melt-solidification are stacked in an order. In such the case, the melt-solidification film is melted to be solidified in a prescribed thickness. Pores between yttria particles in the melt-solidification film are controlled to be performed of densification as compared to the film without melt-solidification. It is desirable that a density range of the yttria film without melt-solidification is between 2.0-4.0/cm³ and a density range of the melt-solidification yttria film is between 4.0-5.0/cm³.

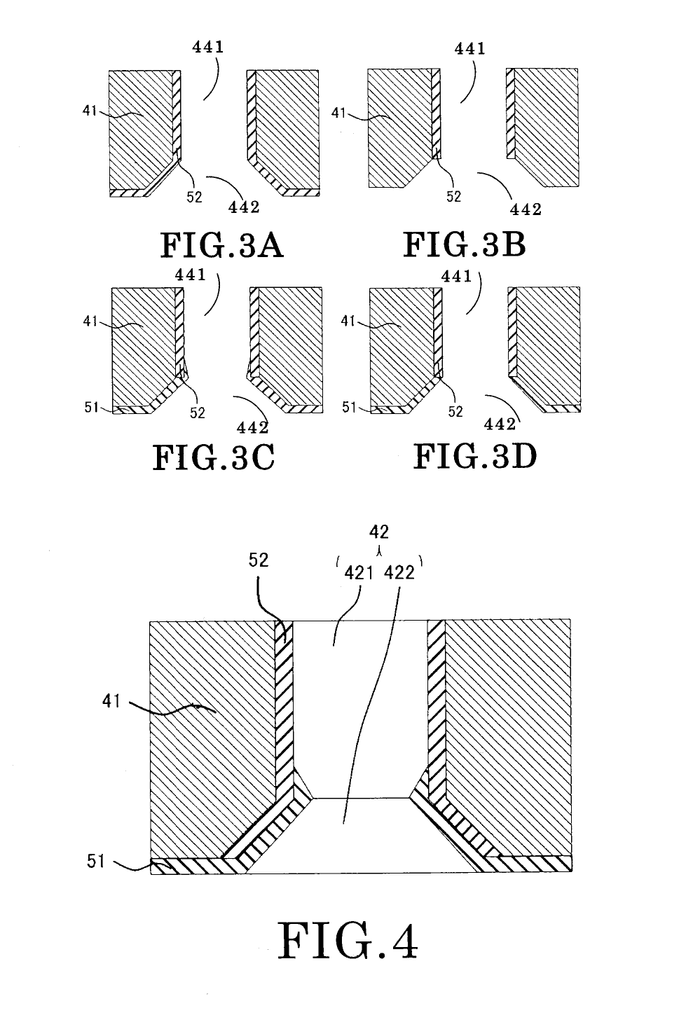

A method of fabricating the protective film 50 on the shower head 41 is described. FIGS. 3A-3D are cross-sectional views showing a method of fabricating the gas supply member according to the first embodiment. As shown in FIG. 3A, a protective film composed of the alumina film 52 with a thickness of 50-100 μm is provided on a sidewall of the shower head 41 with the gas supply path 42 at the downstream side, which is the side of the exhaust port 422, and a sidewall from the exhaust port 422 to a portion of the first channel 421.

As shown in FIG. 3B, a portion of the alumina film 52 on a sidewall constituting the exhaust port 422, which is a main surface and the taper surface, is removed to leave only the alumina film 52 on the first channel. The alumina film is removed by sandblast technique in which fine alumite particles is sprayed, for example.

As shown in FIG. 3C, the yttria film 51 as the protective film is formed on the sidewall at the downstream side of the shower head 41 with the gas supply path 42 (the sidewall at the side of the exhaust port 422) and the main surface of the shower head 42.

As a method of forming the protective film, spray method, chemical vapor deposition, aerosol deposition, cold spray method, gas deposition, electrostatic particle bombardment coating method and bombardment sintering method or the like can be employed.

As shown in FIG. 3D, the yttria film 51 formed on the alumina film 52 in the first channel 421 is removed by polishing or the like, for example. In such a manner, the yttria film 51 is provided only on one surface, which is a lower surface, constituting the bend portion 43 of the shower head 41. The shower head 41 as shown in FIG. 2 can be obtained described above.

In forming the yttria film 51 in FIG. 3C, the yttria film 51 can be performed to be surface treatment so that the yttria film 51 is melted to be solidified in the thickness range after forming the yttria film 51 by spray method, chemical vapor deposition, aerosol deposition, cold spray method, gas deposition, electrostatic particle bombardment coating method and bombardment sintering method or the like. As the surface treatment, selectively thermal melting, laser annealing, plasma jet technique or the like, for example, can be utilized.

Effects of the first embodiment as compared to a comparative case are described. FIG. 4 is a cross-sectional view showing a gas supply member according to a comparative case. A gas supply path 42 is provided in a shower head 41, which is a gas supply member, to penetrate into the member of the shower head 41 from the upper surface to the lower surface of the shower head 41. The gas supply path 42 includes a first channel 421 with a first diameter and an exhaust port 422 connected to the first channel 421. The exhaust port 422 acts as the second channel in which a diameter is increased from one end portion connected to the channel 421 with the first diameter to the other end with a second diameter being larger than the first diameter. An alumina film 52 is provided on both a surface at the downstream side of the shower head 41 and a sidewall of the exhaust port 422. In other words, the structure is constituted that the alumina film 52 is also provided on the sidewall constituting the exhaust port 422.

Generally, a difference of linier expansion coefficients between aluminum and alumina or yttria is large, linier expansion coefficients of aluminum, alumina, yttria being 24×10⁻⁶/C°, and 7×10⁻⁶/C° or the like, respectively. Therefore, cracks are easily generated in the alumina film 52 when the thermal expansion of the each film is occurred by heating in the plasma processing. Especially, the linear expansion coefficient of alumina is smaller than that of yttria, and alumina is adhered to aluminum. Accordingly, the cracks are easily generated in alumina than yttria.

On the other hand, the alumina film 52 is provided on the sidewall of the first channel 421 of the shower head 41 in the first embodiment as shown in FIG. 2. The alumina film 52 is not provided on the sidewall constituting the exhaust port 422 but the yttria film 51 is directly provided. Accordingly, cracks are hardly generated in the yttria film 51 strongly adhered to the shower head 41 when a difference of thermal expansions between the shower head 41 and the yttria film 51 is generated in the plasma processing.

The alumina film 52 is provided on the sidewall of the first channel 421 of the shower head 41 in the gas supply member according to the first embodiment, and the alumina film 52 is not provided on the surface, which is also the sidewall, constituting the exhaust port 422 but the yttria film 51 is directly provided. In such the structure, the cracks is hardly generated in the yttria film 51 strongly adhered to the shower head 41 such that yttria particles can be prevented to escape from the yttria film 51 when the thermal expansion difference between the shower head 41 and the yttria film 51 is generated by heating in the plasma processing.

### Second Embodiment

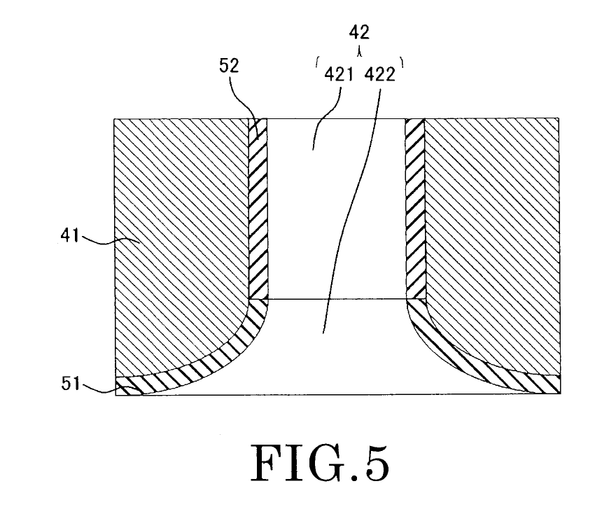

FIG. 5 is a cross-sectional view showing a gas supply member according to a second embodiment. In the first embodiment as shown in FIG. 2, the sidewall of the material constituting the exhaust port 422 of the shower head 41 and the sidewall at the downstream side of the gas does not a curved surface but each of the planer surfaces are crossed by a prescribed angle to have an adjacent corner. On the other hand, the surface of the material constituting the exhaust port 422 of the shower head 41 and the sidewall at the downstream side of the gas is connected by a smooth curved surface in the second embodiment as shown in FIG. 5. A diameter of an opening of the exhaust port 422 is increased with separating from the connection portion to the first channel 421. As a result, the curved surface of the exhaust port 422 is constituted such that a diameter of the opening in the sidewall at downstream side of the shower head 41 is larger than the first diameter. The sidewall constituting the exhaust port 422 has curve surfaces in FIG. 5. However, it is not restricted the above case. A portion near a connection between the sidewall of the exhaust port 422 and the sidewall at downstream side of the shower head 41 is constituted with a curved surface. In the above situation, the portion near the connection is corresponded to the corner 44 in FIG. 6. The sidewall at the downstream side of the shower head 41 is faced to an area in which plasma is generated, when the gas introduced from the exhaust port 422 becomes a plasma state. A curvature of the curved surface constituting the exhaust port 422 of the shower head 41 is desired to be nearly in a range of 100-500 μm in FIG. 5.

A thickness of the protective film 50 formed on the sidewall of the exhaust port 422 of the shower head 41 can be nearly a predetermined value or can be thinner with nearer to the center of the exhaust port 422.

Another conditions or the like are the same as the first embodiment. Accordingly, the explanation is omitted. The yttria film 51 and the alumina film 5 2 are used as the same in the first embodiment. Furthermore, a method of the yttria film constituting the productive film can be also used the same method as the first embodiment.

As the sidewall of the underlying exhaust port 422 of the shower head 41 is formed as the curved surface and the yttria film 51 is formed on the curved surface according to the second embodiment, stress concentrated to the corner is further relaxed to prevent crack generation as compared to the first embodiment.

The protective film formed on shower head 41 of RIE apparatus is explained in the first and second embodiments for example. However, it is not restricted to the above case. The protective film 50 can be provided on a member other than the shower head 41, the inner wall of the vacuum chamber 11, the baffle plate 24, the focus ring 23, the support table 21 retaining the sample to be processed by plasma or the like, for example, according to the first and second embodiments.

Furthermore, RIE is explained as the plasma processing apparatus 10, for example, in the first and second embodiments. However, the embodiments are described above can be applied to all of processing apparatus or semiconductor manufacturing apparatus including an asher, a chemical dry etcher, a chemical vapor deposition or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A gas supply member, comprising:
a body; and
a gas supply path penetrating into the body, the gas supply path including a first channel at an inlet side and a second channel connected to the first channel at an outlet side, the first channel having a first diameter and a diameter of the second channel being monotonically increased towards the outlet side from the first diameter to a second diameter;
wherein an alumina film is provided on a first sidewall of the first channel, and an yttrium-containing film is provided on a second sidewall of the second channel and a surface of the body at the outlet side.

2. The gas supply member of claim 1, wherein
the yttria-containing film is not provided on the first sidewall.

3. The gas supply member of claim 1, wherein
the second sidewall has a taper shape.

4. The gas supply member of claim 1, wherein
the second sidewall has a curved shape.

5. The gas supply member of claim 1, wherein
a side surface of the alumina film and a side surface of the yttria-containing film are contacted each other, and the side surfaces have a same length in each direction to each film surface.

6. The gas supply member of claim 1, wherein
the yttria-containing film has a thickness of 50-100 μm.

7. The gas supply member of claim 1, wherein
the yttria-containing film includes a melt-solidification film.

8. The gas supply member of claim 7
the melt-solidification film has a prescribed thickness in a range of the thickness of the yttria-containing film.

9. The gas supply member of claim 7, wherein
the yttria-containing film has a stacked structure in which the melt-solidification film and the yttria-containing film without melt-solidification are stacked in an order.

10. The gas supply member of claim 1, wherein
the yttria-containing film has a density of 1.0-4.0 cm³.

11. The gas supply member of claim 4, wherein
the curved shape has a curvature of 50-100 μm.

12. The gas supply member of claim 11, wherein
a thickness of the yttria-containing film provided on the surface of the body at the outlet side is decreased in the outlet side direction.

13. A method of fabricating a gas supply member, comprising:
providing a gas supply path penetrating into a body, the gas supply path including a first channel at an inlet side and a second channel connected to the first channel at an outlet side, the first channel having a first diameter and a diameter of the second channel being monotonically increased towards the outlet side from the first diameter to a second diameter;
providing an alumina film on a first sidewall of the first channel and a second sidewall of the second channel;
removing the alumina film on a second sidewall of the second channel and a surface of the body at the outlet side;
providing an yttrium-containing film on the second sidewall of the second channel and the surface of the body at the outlet side; and
removing the yttrium-containing film on the alumina film.

14. The method of claim 13, wherein
the alumina film is removed by sandblast.

15. The method of claim 13, wherein
the yttrium-containing film is provided by using at least one of spray, chemical vapor deposition, aerosol deposition, cold spray, gas deposition, electrostatic particle bombardment coating and bombardment sintering.

16. The method of claim 13, further comprising:
a surface treatment is performed to the yttrium-containing film after providing the yttrium-containing film.

17. The method of claim 16, wherein
melt-solidification is used as the surface treatment.

18. The method of claim 16, wherein
selective melting is used as the surface treatment.

19. The method of claim 16, wherein laser annealing or plasma jet is used as the selective melting.

20. A plasma processing apparatus, comprising:
a chamber;
a holding unit configured to hold a sample to be processed in the chamber;
a plasma generation unit configured to generate plasma in gas introduced in the chamber; and
a gas supply member including, a body and a gas supply path penetrating into the body, the gas supply path including a first channel at an inlet side and a second channel connected to the first channel at an outlet side, the first channel having a first diameter and a diameter of the second channel being monotonically increased towards the outlet side from the first diameter to a second diameter, a surface of the gas supply member being placed to be opposed to the holding unit,
wherein an alumina film is provided on a first sidewall of the first channel, an yttrium-containing film is provided on a second sidewall of the second channel and a surface of the body at the outlet side.
